(19) United States
(12) Patent Application Publication
(10) Pub. No.: US 2006/0208324 A1
(43) Pub. Date: Sep. 21, 2006

(54) Linear device

(76) Inventors: Yasuhiko Kasama, Sendai-shi (JP); Kenji Omote, Sendai-shi (JP)

Correspondence Address: YOUNG & THOMPSON, 745 SOUTH 23RD STREET, 2ND FLOOR, ARLINGTON, VA, 22202, US

(21) Appl. No.: 10/568,312

(22) PCT Filed: Aug. 19, 2004
(86) PCT No.: PCT/JP04/11928

§ 371 Date: May 17, 2006

(30) Foreign Application Priority Data
Aug. 19, 2003 (JP) 2003-294807
Sep. 12, 2003 (JP) 2003-321027

(51) Int. Cl. H01L 29/76

(52) U.S. Cl. 257/401

(57) ABSTRACT

A linear MISFET is resilient, flexible and capable of being fabricated into an integrated circuit in an arbitrary shape. Typically a structure includes a source region and drain region arranged in parallel. However, since a channel length of the MISFET for determining the electric characteristics thereof is determined by a distance between the source region and the drain region across a cylindrical gate insulating region, it has been difficult to downsize the channel length or improve reproducibility thereof. The present MISFET includes a semiconductor region serving as a channel region interposed between a source region(s) and a drain. Application of control voltage to the semiconductor region through the gate insulating region, controls electric current flowing between the source regions and drain region(s). The channel length is determined by a film thickness of the semiconductor region, thereby enabling downsizing and improvement of reproducibility, of the channel length.

### TECHNICAL FIELD

The present invention relates to a linear device comprising a MISFET formed in a linear body.

### BACKGROUND ART

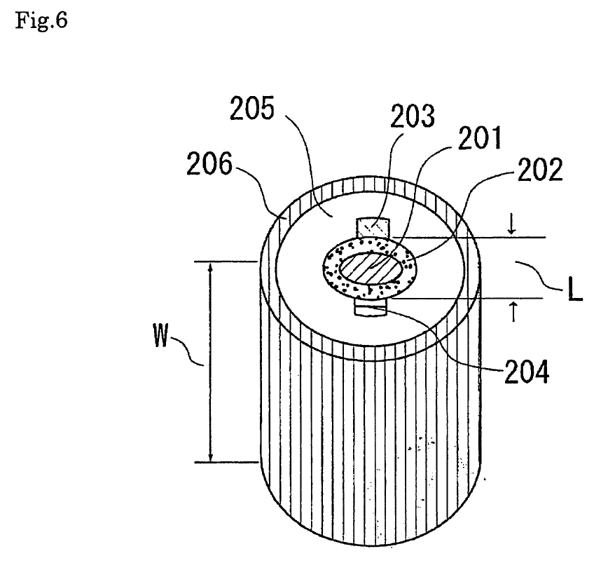

It is possible to create various devices in arbitrary shapes, by utilizing linear devices each including a circuit element formed into a thread and by utilizing integrated circuits fabricated by such linear devices, since such linear devices and integrated circuits have resiliency and flexibility. FIG. 6 is a perspective view of a conventional linear device including a MISFET formed as a circuit element. The device includes a gate electrode 201 at a center of a cross section of the device, as well as a gate insulating region 202, a source region 203, a drain region 204, and a semiconductor region 205 sequentially formed outside the gate electrode. Application of control voltage to the gate electrode 201 controls electric current flowing through the semiconductor region 205 acting as a channel between the source region and drain region.

### DISCLOSURE OF THE INVENTION

### Problem to be Solved by the Invention

The conventional MISFET shown in FIG. 6 has a channel length to be determined by a distance L between the source region 203 and drain region 204 along a surface of the insulating region 202. As such, the channel length has a fabrication accuracy depending on positional accuracies of the source region 203 and drain region 204 arranged in a linear body comprising the gate electrode and gate insulating region. Production methods of linear MISFETs include one configured to simultaneously feed gel-like polymer materials acting as starting materials of a gate electrode, a gate insulating region, a source region, a drain region, and a semiconductor region, respectively, into a die for controlling a cross-sectional shape of a circuit element, in a manner to eject the polymer materials from the die into a linear form which is to be subsequently solidified. This method is problematic in insufficient uniformity and insufficient reproducibility of channel lengths, due to non-uniformity of viscosities, thermal expansion coefficients, and the like of gel-like polymer materials, respectively.

Further, although there exists another production method for forming a gate electrode/gate insulating region, a source region, and a drain region as separate linear bodies, respectively, and for bundling up the linear bodies to thereby form the structure shown in FIG. 6, it fails to attain a sufficiently high precision, due to dependency of a channel length on positional accuracies in a bundling procedure. As such, about 1 μm has been a limitation of downsizing of a channel length in any one of the above situations, and it has been difficult to improve high-frequency characteristics, degree of integration, and the like by a downsized channel length.

### Means for Solving the Problem

There is provided a linear device comprising a MISFET having a structure including, in a radial direction within a cross section of a device region: a film-like semiconductor region serving as a channel region interposed between a source region and a drain region; and a gate insulating region having a part contacted with the semiconductor region.

The present invention (1) resides in a linear device including a gate electrode, a gate insulating region, a source region, a drain region, and a semiconductor region, characterized in

that the semiconductor region is arranged between the source region comprising one or a plurality of source region(s) and the drain region comprising one or a plurality of drain region(s), in a radial direction within a cross section of a device region, so that a part of the gate insulating region is contacted with the semiconductor region.

The present invention (2) resides in the linear device of the invention (1), wherein the gate electrode and the gate insulating region are arranged inside or outside the source region(s) and the drain region(s).

The present invention (3) resides in the linear device of the invention (1) or (2), wherein the linear device comprises, at a center, one of: a hollow region; an electric conductor region; the gate electrode; the source region; the drain region; another insulating region different from the gate insulating region; and another semiconductor region different from the semiconductor region.

The present invention (4) resides in the linear device of any one of the inventions (1) through (3), wherein the linear device comprises a plurality of device regions through separation regions therebetween, respectively, in a longitudinal direction of a linear body constituting the linear device.

The present invention (5) resides in the linear device of any one of the inventions (1) through (4), wherein the gate electrode, gate insulating region, source region(s), drain region(s), and/or semiconductor region constituting the linear device are formed of an organic semiconductor or electroconductive polymer.

### Effect of the Invention

Since the MISFET has a structure including the semiconductor region serving as the channel region between the source region(s) and the drain region (s) in a radial direction within a cross section of the device region, the channel has a length to be determined by the film thickness of the semiconductor region. This enables downsizing, and improvement of reproducibility and uniformity, of the channel length.

Forming a hollow region at a center of the linear device enables a lightened weight of the linear body constituting the linear device. Alternatively, forming an electric conductor region enables a decreased electrode resistance or wiring resistance in the linear device. Alternatively, forming an insulating region facilitates electric separation of a plurality of linear devices formed in the linear body. Alternatively, forming a semiconductor region enables formation of a diode comprising a PN junction, for example, at the central part of the linear body. Forming a plurality of MISFETs in the longitudinal direction of a linear device facilitates formation of an integrated circuit comprising the linear device, thereby also effectively improving a degree of integration.

Forming the gate electrode, gate insulating region, source region(s), drain region(s), and/or semiconductor region from an organic semiconductor or electroconductive polymer, decreases a material cost and simplifies a production process, thereby effectively decreasing a production cost.

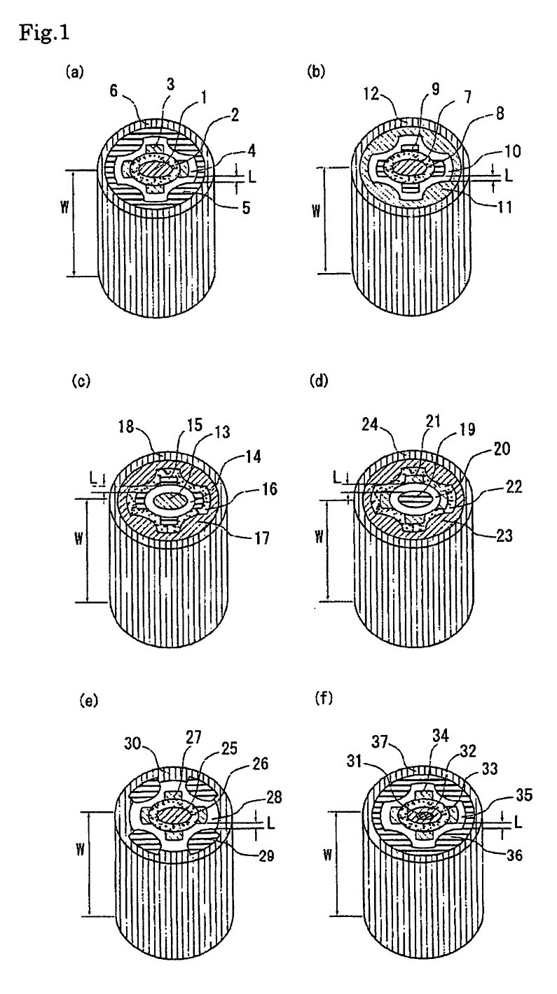

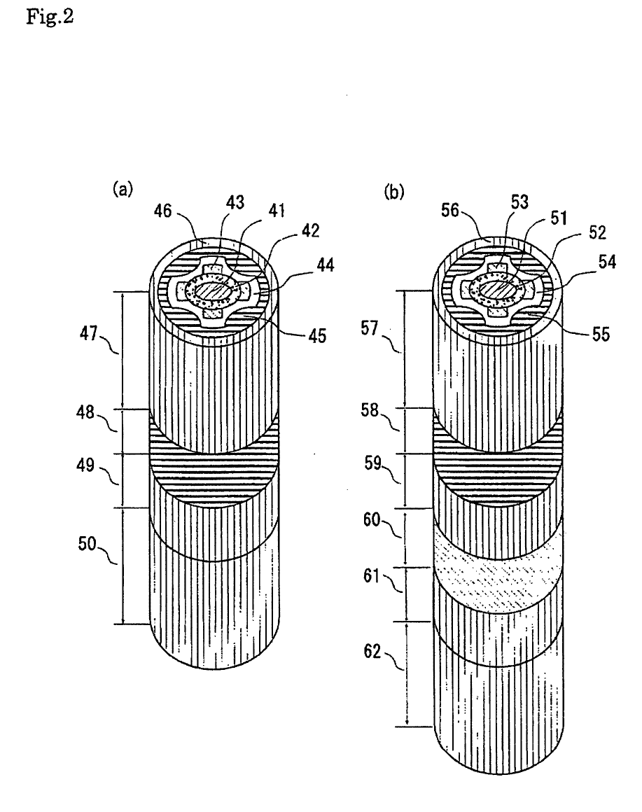

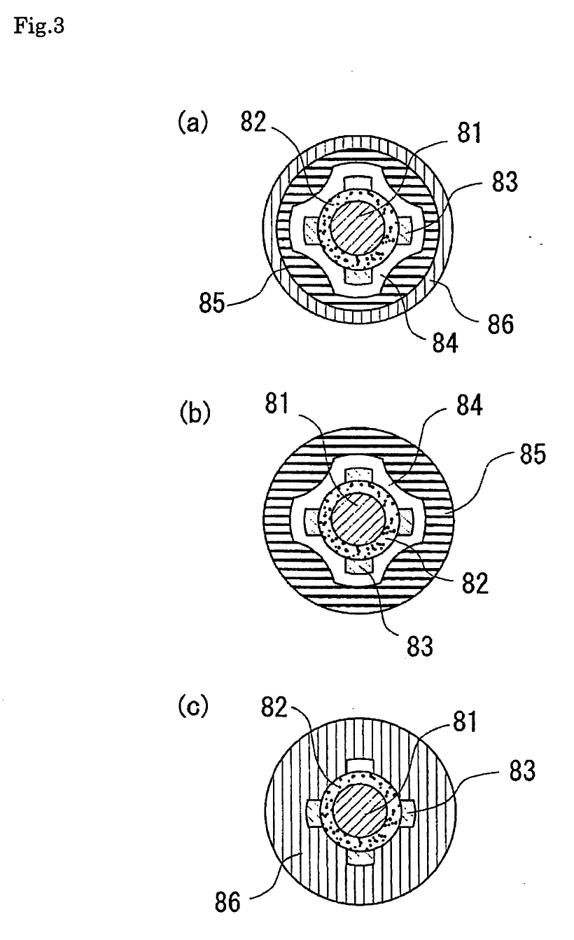

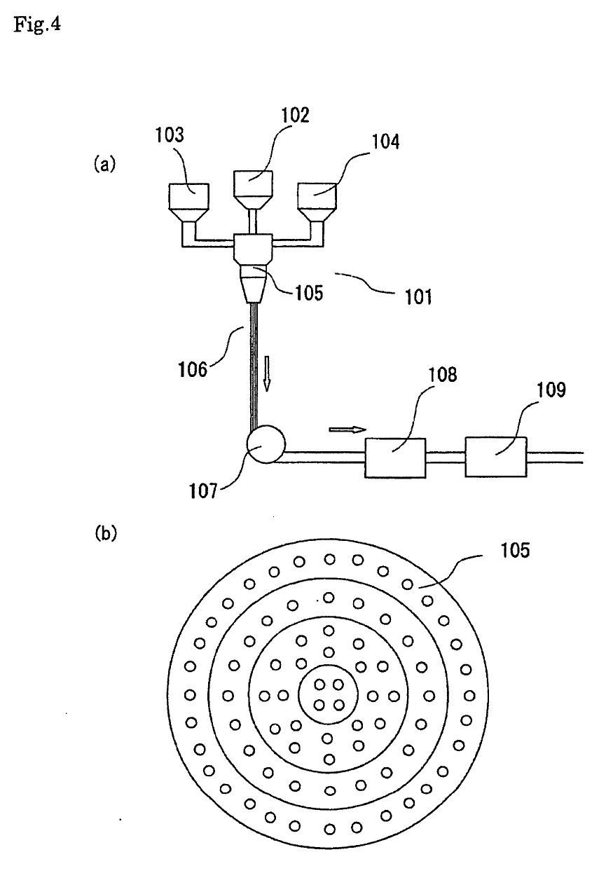

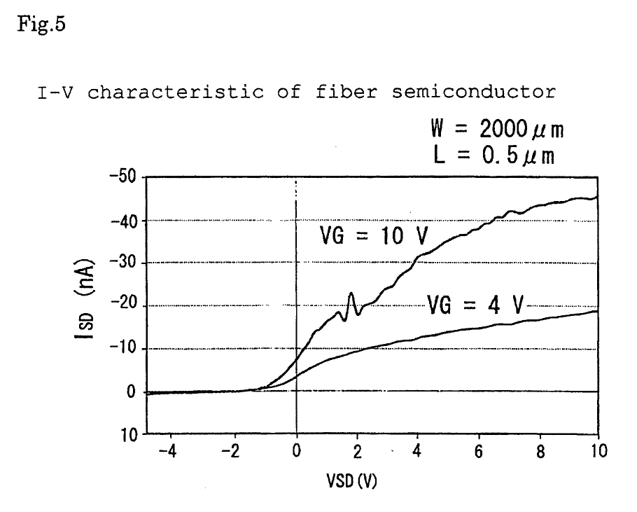

### BRIEF DESCRIPTION OF THE DRAWINGS

[FIG. 1] (a) through (f) are perspective views of linear devices of the present invention, respectively.

[FIG. 2] (a) and (b) are perspective views of linear bodies each comprising a plurality of linear devices of the present invention, respectively.

[FIG. 3] (a) through (c) are cross-sectional views of the linear device of the present invention, respectively.

[FIG. 4] (a) is a front view of a production apparatus of the linear device of the present invention, and (b) is a plan view of a die to be used for production of the linear device of the present invention.

[FIG. 5] A graph of electric characteristics of the linear device of the present invention.

[FIG. 6] A perspective view of a conventional linear device.

### EXPLANATION OF REFERENCE NUMERALS

1, 7, 17, 23, 25, 32, 41, 51, 81, 201 gate electrode
2, 8, 16, 22, 26, 33, 42, 52, 82, 202 gate insulating region
3, 11, 13, 21, 27, 34, 43, 53, 83, 203 source region
4, 10, 14, 20, 28, 35, 44, 54, 84, 205 semiconductor region
5, 9, 15, 19, 29, 36, 45, 55, 85, 204 drain region
6, 12, 18, 24, 30, 37, 46, 56, 86, 206 surface protection region
31 center region
47, 50, 57, 62 device region
49, 59, 61 separation region
60 source extraction electrode
48, 58 drain extraction electrode
101 extrusion apparatus
102 starting material 1 reservoir
103 starting material 2 reservoir
104 starting material 3 reservoir
105, 110 die
106 linear body
107 roller
108 doping treatment part
109 electrode formation treatment part

### BEST MODE FOR CARRYING OUT THE INVENTION

There will be clarified definitions of terms in the present invention, together with explanation of the best mode of the present invention. Note that Japanese Patent Application No. 2002-131011 as a basis of a priority of the present application is incorporated herein in its entirety by reference. Further, the technical scope of the present invention is not limited at all by the best mode (structure, shape, material, and the like) to be described hereinafter.

The phrase “radial direction within a cross section of a device region” means a direction from a cross section center of a linear device toward an outer edge thereof.

The phrase “between one or a plurality of source region(s) and one or a plurality of drain region(s)” means that distances from a cross section center of a linear device to the one or the plurality of source region(s) and to the one or the plurality of drain region(s) are different from each other (i.e., it is possible for a semiconductor region to be interposed between the source region(s) and drain region(s)). Here, in a case where a plurality of source regions and/or drain regions is present, although distances from a center to the same type of regions are preferably the same among the respective regions, one(s) or all of the distances among the same type of regions may be different from the others or from each other. Moreover, in a case where a plurality of source regions and/or drain regions is present, any source regions or drain regions are not required to be present in the same radial direction as the corresponding drain regions or source regions, respectively.

(Structure of Linear Device)

There will be firstly explained structures of linear devices of the present invention, with reference to concrete examples, shown in the drawings, respectively.

### FIRST CONCRETE EXAMPLE

FIG. 1(a) is a perspective view of a linear device according to a first concrete example of the present invention. The linear device according to the first concrete example of the present invention comprises, within a cross section of the linear device: a linear gate electrode 1 located at a center; and a gate insulating region 2, source regions 3, a semiconductor region 4, a drain region 5, and a surface protection region 6 of an insulating nature, which are sequentially arranged around the gate electrode outwardly therefrom. Further, the source regions 3 are provided in a manner divided into a plurality of linear bodies, so that a part of the gate insulating region 2 is contacted with the semiconductor region 4.

(Function of Linear MISFET)

Application of a gate voltage to the gate electrode causes the gate voltage to act on the semiconductor region, in an area where the gate insulating region contacts with the semiconductor region.

In case of an N-type MISFET, application of a gate voltage, which is positive relative to a potential of a semiconductor region, to a gate electrode causes accumulation of electrons acting as electroconductive carriers within the semiconductor region in a manner to enhance an electric conductivity of the semiconductor region serving as a channel region between a source region and a drain region, so that an electric current flowing between the source region and the drain region can be controlled by the gate voltage.

In case of a P-type MISFET, application of a gate voltage, which is negative relative to a potential of a semiconductor region, to a gate electrode causes accumulation of holes acting as electroconductive carriers within the semiconductor region in a manner to enhance an electric conductivity of the semiconductor region serving as a channel region between a source region and a drain region, so that an electric current flowing between the source region and the drain region can be controlled by the gate voltage applied to the gate electrode.

In FIG. 1(a), the MISFET has a channel width to be determined by a longitudinal length denoted by “W” of the linear body constituting the linear device. In turn, the MISFET has a channel length to be determined by a film thickness of the semiconductor region 4 denoted by “L” in FIG. 1(a). Thus, the fabrication accuracy of the channel length depends on the fabrication accuracy of the film thickness of the semiconductor region 4 (i.e., the distance between the source region(s) and the drain region). Fabrication accuracies of film thicknesses in case of production of linear devices by methods of extruding gel-like polymers and in case of production of linear devices by methods of bundling up linear bodies, are remarkably excellent as compared with arrangement accuracies of linear bodies which have determined fabrication accuracies of channel lengths in the related art, so that fabrication accuracies can be improved to about 10 to 1,000 times by the firstly mentioned methods. Thus, the linear device of the present invention enables downsizing, and improvement of reproducibility and uniformity, of the channel length.

In addition to positional relationships among the respective regions constituting the linear device in the first concrete example of the present invention, there are several modified examples. Although the explanation of the first concrete example has been conducted with respect to the function of the linear device, also those linear devices of other concrete examples of the present invention to be described hereinafter each function in the same manner as the first concrete example.

### SECOND CONCRETE EXAMPLE

There is provided a second concrete example which is different from the first concrete example, in arrangement of source region and drain region.

FIG. 1(b) is a perspective view of a linear device according to the first concrete example. The linear device according to the first concrete example of the present invention comprises, within a cross section of the linear device: a linear gate electrode 7 located at a center; and a gate insulating region 8, drain regions 9, a semiconductor region 10, a source region 11, and a surface protection region 12 of an insulating nature, which are sequentially arranged around the gate electrode outwardly therefrom. Further, the drain regions 9 are provided in a manner divided into a plurality of linear bodies, so that a part of the gate insulating region 8 is contacted with the semiconductor region 10.

### THIRD CONCRETE EXAMPLE

Although the first concrete example and second concrete example each provide the associated linear device having a structure where the gate electrode and gate insulating region are arranged inside the source region and drain region, there is provided a linear device by each of a third concrete example and a fourth concrete example such that the linear device has a structure including a gate electrode and a gate insulating region arranged outside a source region(s) and a drain region(s).

FIG. 1(c) is a perspective view of a linear device according to the third concrete example. The linear device according to the third concrete example of the present invention comprises, within a cross section of the linear device: a linear source region 13 located at a center; and a semiconductor region 14, drain regions 15, a gate insulating region 16, a gate electrode 17, and a surface protection region 18 of an insulating nature, which are sequentially arranged around the source region outwardly therefrom. Further, the drain regions 15 are provided in a manner divided into a plurality of linear bodies, so that a part of the gate insulating region 16 is contacted with the semiconductor region 14.

### FOURTH CONCRETE EXAMPLE

The fourth concrete example is different from the third concrete example, in arrangement of source region and drain region.

FIG. 1(d) is a perspective view of a linear device according to the fourth concrete example. The linear device according to the fourth concrete example of the present invention comprises, within a cross section of the linear device: a linear drain region 19 located at a center; and a semiconductor region 20, source regions 21, a gate insulating region 22, a gate electrode 23, and a surface protection region 24 of an insulating nature, which are sequentially arranged around the drain region outwardly therefrom. Further, the source regions 21 are provided in a manner divided into a plurality of linear bodies, so that a part of the gate insulating region 22 is contacted with the semiconductor region 20.

### FIFTH CONCRETE EXAMPLE

There is provided a fifth concrete example which is different from the first concrete example, in that the former includes not a single continuous drain region but a plurality of divided drain regions.

FIG. 1(e) is a perspective view of a linear device according to the fifth concrete example. The linear device according to the fifth concrete example of the present invention comprises, within a cross section of the linear device: a linear gate electrode 25 located at a center; and a gate insulating region 26, source regions 27, a semiconductor region 28, drain regions 28, and a surface protection region 30 of an insulating nature, which are sequentially arranged around the gate electrode outwardly therefrom. Further, the source regions 27 are provided in a manner divided into a plurality of linear bodies, so that a part of the gate insulating region 26 is contacted with the semiconductor region 28.

Further, the drain regions 29 are provided in a divided manner, to thereby decrease areas thereof overlapped with the source regions 27. This effectively decreases a parasitic capacitance between the source and drain, thereby enabling a high-speed operation of a circuit constituted of the linear device. It is possible to obtain the same effect as the above, not only in the first concrete example but also in the second through fourth concrete examples, by dividing the applicable source region and drain region to thereby decrease a parasitic capacitance.

### SIXTH CONCRETE EXAMPLE

There is provided a sixth concrete example which is different from the first concrete example, in that the former includes a center region located at a center of a linear body constituting a linear device.

FIG. 1(f) is a perspective view of a linear device according to the sixth concrete example. The linear device according to the sixth concrete example of the present invention comprises, within a cross section of the linear device: the center region 31 located at a center; and a gate electrode 32, a gate insulating region 33, source regions 34, a semiconductor region 35, a drain region 36, and a surface protection region 37 of an insulating nature, which are sequentially arranged around the center region outwardly therefrom. Further, the source regions 34 are provided in a manner divided into a plurality of linear bodies, so that a part of the gate insulating region 33 is contacted with the semiconductor region 35.

Forming a hollow region as the center region 31 enables a lightened weight of the linear body constituting the linear device. Alternatively, forming an electric conductor region enables a decreased electrode resistance or wiring resistance. Alternatively, forming an insulating region facilitates electric separation of a plurality of linear devices formed in the linear body. Alternatively, forming a semiconductor region enables formation of a diode comprising a PN junction, for example, at the central part of the linear body. It is possible to obtain the same effect as the above, not only in the first concrete example but also in the second through fourth concrete examples, by providing a center region comprising the above-described material or the like at the center of the linear body

Although the first through sixth concrete examples have been each described about the situation where the number of dividedly provided source regions or drain regions is 4, the effects of the present invention can be equally obtained even in a case of a MISFET having dividedly provided source regions or drain regions the number of which is 2, 3, 5, . . . , and the like differently from the above.

(Extraction Electrode)

As a method for electrically connecting the gate electrode, source region(s), drain region(s), and semiconductor region of each of the linear devices of the present invention to an external circuit(s), it is possible to provide connection terminals at the respective regions at an end of the linear body constituting the applicable linear device so as to connect the connection terminals to the external circuit(s). It is alternatively possible to extract a connection terminal(s) from a side surface of the linear body, by establishing a part of the linear body constituting the linear device into an extraction electrode region.

(Plurality of Linear Devices)

It is possible to form a plurality of linear devices within one linear body. Further, it is preferable to form a separation region(s) between device regions so as to electrically separate one device region from the other(s).

Forming a plurality of linear devices within a linear body facilitates fabrication of an integrated circuit comprising the linear devices, thereby also effectively improving a degree of integration. Forming a plurality of MISFETs in the longitudinal direction of a linear device facilitates formation of an integrated circuit comprising a plurality of MISFETs having a common gate electrode centrally located through the MISFETs. Similarly, arranging a source electrode at a center facilitates formation of an integrated circuit comprising a plurality of MISFETs commonly having the source electrode. Alternatively, arranging a drain electrode at a center facilitates formation of an integrated circuit comprising a plurality of MISFETs commonly having the drain electrode.

Examples of a linear device to be formed within a linear body includes not only a MISFET, but also an active device such as bipolar transistor, JFET, and SIT, and a passive device such as diode, capacitor, and resistance. It is also possible to form a photoelectric conversion device such as light emitting device, displaying device, photocell, photosensor, and the like.

FIGS. 2(a) and (b) are perspective views of linear bodies each comprising a plurality of linear devices of the present invention, respectively.

In FIG. 2(a), formed in one linear body are two linear devices each having the same cross-sectional structure as that of the linear device shown in FIG. 1(a). The first linear device is formed in a device region 47, and so is the second linear device in a device region 50. Formed between the device region 47 and the device region 50 is an extraction electrode 48 electrically connected to a drain region 45 of the first linear device. The first linear device has a gate electrode and a source region which are electrically connected to a gate electrode and a source region of the second linear device, respectively. Meanwhile, drain regions and semiconductor regions are electrically separated by a separation region 49.

FIG. 3(a) is a cross-sectional view of the linear body at the device region 47 of the linear device shown in FIG. 2(a). Arranged sequentially around and outwardly from a gate electrode 81 at a center, are a gate insulating region 82, source regions 83, a semiconductor region 84, a drain region 85, and a surface protection region 86.

FIG. 3(b) is a cross-sectional view of the linear body at the extraction electrode 48 of the linear device shown in FIG. 2(a). Arranged sequentially around and outwardly from the gate electrode 81 at the center, are the gate insulating region 82, the source regions 83, the semiconductor region 84, and the drain region 85. The extraction electrode 48 has a surface which is not covered by an insulating surface protection region, thereby enabling an electrical connection to the drain region 85 at a side surface of the linear body.

FIG. 3(c) is a cross-sectional view of the linear body at the separation region 49 of the linear device shown in FIG. 2(a). Arranged sequentially around and outwardly from the gate electrode 81 at the center, are the gate insulating region 82, the source regions 83, and the surface protection region 86. Since the surface protection region 86 is insulative, the semiconductor region and drain region of the first linear device are electrically separated from those of the second linear device, respectively.

FIG. 2(b) shows an example including a drain extraction electrode and a source extraction electrode formed at a side surface of a linear body. The linear body includes a first linear device formed in a device region 57 and a second linear device formed in a device region 62. Electrically connected to a drain region of the first linear device is a drain extraction electrode 58, and electrically connected to a source region of the first linear device is a source extraction electrode 60. The drain extraction electrode 58 and source extraction electrode 60 are electrically separated from each other, by a separation region 59.

(Material of Linear Device)

In case of a linear device which is an N-type MISFET, it includes: a gate electrode formed of a P-type or N-type semiconductor material or electroconductive material; a semiconductor region formed of a P-type semiconductor material; and a source region and a drain region each formed of an N-type semiconductor material or electroconductive material. Further, it includes a gate insulating region and a surface protection region each formed of an insulating material.

Further, in case of a linear device which is a P-type MISFET, it includes: a gate electrode formed of a P-type or N-type semiconductor material or electroconductive material; a semiconductor region formed of an N-type semiconductor material; and a source region and a drain region each formed of a P-type semiconductor material or electroconductive material. Further, it includes a gate insulating region and a surface protection region each formed of an insulating material.

As a semiconductor material and an electroconductive material for forming the linear device of the present invention, it is desirable to adopt an organic semiconductor or electroconductive polymer. Adopting the organic semiconductor or electroconductive polymer decreases a material cost and simplifies a production process, thereby effectively decreasing a production cost.

Usable as an electroconductive polymer are polyacetylenes, polyacenes, polythiophenes, poly(3-alkylthiophene), oligothiophene, polypyrrole, polyaniline, polyphenylenes, and the like. It is preferable to select one(s) of them as an electrode or semiconductor layer in consideration of an electrical conductivity and the like. For an electroconductive polymer, it is desirable to mix fullerene or containing-fullerene therewith. Desirable as fullerene is Cn (n=60 to 90). Desirable as a contained atom(s) of containing-fullerene is Na, Li, H, N, or F.

Further, preferably used as an organic semiconductor are polyparaphenylenes, polythiophenes, poly(3-methylthiophene), polyfluorenes, or polyvinylcarbazole.

Moreover, usable as a material of a source/drain region or semiconductor region, is the above-described semiconductor material including a dopant mixed therewith.

For establishment of an N-type semiconductor, it is enough to adopt alkali metal (Li, Na, K), AsF₅/AsF₃, ClO₄ as a dopant, for example.

For establishment of a P-type semiconductor, it is enough to adopt halogen (Cl₂, Br₂, I₂, or the like), Lewis acid (PF₅, AsF₅, SbF₅, or the like), proton acid (HF, HCl, HNO₃, or the like), transition metal compound (FeCl₃, FeOCl, TiCl₄, or the like), electrolyte anion (Cl⁻, Br⁻, I⁻, or the like) as a dopant, for example.

Further, usable as an insulating material for the gate insulating region constituting the linear device of the present invention, are PVDF (polyvinylidene fluoride), PS (polystyrene), PMMA (polymethylmethacrylate), and PVA (polyvinyl alcohol), for example.

Moreover, usable as an insulating material for the surface protection region constituting the linear device of the present invention, are PVDF (polyvinylidene fluoride), PS (polystyrene), PMMA (polymethylmethacrylate), PVA (polyvinyl alcohol), PC (polycarbonate), PET (polyethylene terephthalate), and PES (polyether sulphone), for example.

(Production Apparatus and Production Method)

FIG. 4(a) is a front view of a production apparatus of the linear device of the present invention, and FIG. 4(b) is a plan view of a die to be used for production of the linear device of the present invention.

Reference numeral 101 designates an extrusion apparatus having starting material reservoirs 102, 103, 104 for holding therein starting materials in molten states, dissolved states, or gel states so as to constitute a plurality of regions, respectively. Although the three starting material reservoirs are presented in the example shown in FIG. 4(a), it is possible to appropriately provide starting material reservoirs correspondingly to a configuration of a linear device to be produced.

The starting material reservoir 102 contains a starting material therein to be fed to a die 105. The die 105 is formed with ejection holes commensurating with a cross section of a linear device to be produced. To be collectively ejected from the ejection holes is a linear body which is wound up by a roller 107 or which is delivered to a next process as required in the linearized state.

The starting material reservoirs 102, 103, 104 hold therein a gate electrode material, a gate insulating region material, a source material, a drain material, and a semiconductor material in a molten or dissolved state, or a gel state, respectively. Meanwhile, the die 105 is formed with holes communicated with the material reservoirs, respectively.

As shown in a plan view of FIG. 4(b), the die 105 is formed at its central part with a plurality of holes for ejecting the gate electrode material. Outwardly and peripherally formed around the holes are a plurality of holes for ejecting the gate insulating region material. Further, outwardly and peripherally formed around the holes are a plurality of holes for ejecting the source material, drain material, and semiconductor material, respectively. However, it is enough in the die 105 that the arrangement of the pluralities of holes for ejecting the materials corresponding to a circuit region is appropriately set correspondingly to a cross-sectional structure of a linear device to be actually produced, and it is not absolutely required that holes for ejecting a gate electrode material are arranged centrally.

The starting materials in a molten or dissolved state, or a gel state are fed from the starting material reservoirs into the die 105, ejected from the die through the holes, and then solidified. Pulling an end of the solidified matter forms a continuous and linear light emitting device in a thread shape. The linear device is wound up by the roller 107. Alternatively, the solidified matter in the thread shape is delivered to the next process as required.

Formation of Extraction Electrode: To contact an extraction electrode with a source region or drain region, there is removed a part of a semiconductor region by a method such as mechanical working, etching, or the like before formation of the electrode. The extraction electrode is formed at an electrode formation treatment part 109, by selectively conducting coating of an electroconductive polymer, vapor deposition of Al, or the like, for example.

Formation of Surface Protection Region: Although not shown in FIG. 4, there is provided a treatment part for coating an insulating material as required, thereby coatingly forming an insulating region at a surface of a linear body constituting a linear device.

Formation of Separation Region: There is selectively removed an electroconductive region or semiconductor region which is intended to be separated, by a method such as mechanical working, etching, or the like, at a portion where the separation region is to be formed. The removed region is coated and formed with an insulating region. Further, it is possible to inject oxygen ions at a doping treatment part 108 followed by heating, thereby forming an insulating separation region.

(Shape of Linear Device)

It is desirable that the linear devices of the present invention are each 10 mm or less, preferably 5 mm or less in outer diameter. 1 mm or less is desirable, and 10 μm or less is more desirable. It is also possible to attain 1 μm or less, and even 0.1 μm or less.

In case of eventually forming an extrafine linear body having an outer diameter of 1 μm or less by discharging it from a hole of a die, there may be caused clogging of the hole, breakage of a thread-like body, or the like. In such a case, there are firstly formed linear bodies of respective regions. Next, these linear bodies may be regarded as many islands, respectively, which are then each surrounded at a periphery (sea) thereof by a meltable matter and subsequently bundled up by a funnel-shaped nozzle followed by discharge into a single linear body. Increasing island components and decreasing sea components enables formation of an extremely fine linear body device. As another method, it is possible to once prepare a thick linear body device, and to subsequently extend it in a longitudinal direction thereof. Alternatively, it is also possible to place a molten starting material(s) into a jet stream to thereby melt blow it into an extrafine one.

Meanwhile, it is possible to attain an aspect ratio of an arbitrary value by extrusion forming. 1,000 or more is desirable in case of a thread shape by spinning. 100,000 or more is also possible, for example. In case of usage after cutting, 10 to 10,000, 10 or less, 1 or less, and 0.1 or less is possible, for small units of linear devices.

The linear device is not particularly limited in cross-sectional shape. For example, it may be circular, polygonal, star-shaped, and so on. It may be a polygonal shape having a plurality of apex angles each defining an acute angle. In turn, it is possible that respective regions each have an arbitrary cross section. Depending on a type of device, it is desirable to provide a region layer in a polygonal shape having apex angles each defining an acute angle, in case of intending a wider contacting area between the region layer and a neighboring one. Note that it is possible to easily realize a desired cross-sectional shape, by preparing an extrusion die in the desired shape. In case that an outermost layer is in a star shape or in a shape having apex angles each defining an acute angle, it is possible to fill an arbitrary material(s) into spaces between neighboring apexes such as by dipping after extrusion forming, thereby changing a property of a device depending on the usage thereof.

In case that the linear body constituting the linear device of the present invention is simultaneously formed with a linear photoelectric conversion device such as a light emitting device, displaying device, photocell, photosensor, and the like, the photoelectric conversion device is allowed to have an increased surface area to effectively improve a photoelectric conversion efficiency, by causing the linear device to have a cross-sectional shape which is polygonal, star-shaped, crescent-shaped, petal-shaped, character-shaped, and so on having an increased surface area.

### Embodiment

Although the present invention will be described in detail with reference to an embodiment, the present invention is not limited to such an embodiment.

### PRODUCTION EXAMPLE

As an embodiment of a linear device of the present invention, there was fabricated a linear device having a structure shown in FIG. 1(e), which comprises: a gate electrode located at a center; and a gate insulating region, source regions, a semiconductor region, drain regions, and an insulating region, which are sequentially arranged around the gate electrode outwardly therefrom.

(Formation of Gate Electrode)

Used as a material of gate electrode line was MEH-PPV (poly-3-hexylthiophene) produced by Aldrich. Firstly, prepared in a 300 ml beaker was a toluene solution of MEH-PPV (10 wt %), and 50 ml of an iodine solution was added thereinto, followed by ultrasonic stirring.

(Formation of Gate Insulating Region)

The gate electrode line was immersed into a dimethylformaldehyde solution including 1 wt % of polyvinylidene fluoride, followed by drying at 80° C., thereby forming a polyvinylidene fluoride film having a thickness of 1 μm on a surface of the gate electrode line.

(Formation of Source Regions)

Prepared in a 300 ml beaker was a xylene solution of MEH-PPV (10 wt %), and 50 ml of an iodine solution was added thereinto, followed by ultrasonic stirring. It was followed by vacuum drying and brought into a film-like solid. This film-like solid was cut into lines having diameters of several mm, and the lines comprising the cut MEH-PPV were extruded by a melt extruder (manufactured by Imoto Machinery Co., Ltd.) into a fiber shape having a diameter of about 0.2 mm. There were prepared four fibers therefrom each having a length of about 10 cm.

The four lines made of MEH-PPV to be established into source regions, respectively, were arranged on the gate electrode line having its surface formed with the gate insulating region. Ends of the lines were fixed by an epoxy resin. This was followed by a heat treatment at 200° C. for 1 hour in a nitrogen environment, thereby welding the four source regions to the gate insulating region.

(Formation of Semiconductor Region)

The linear body having a surface formed with the source regions was immersed in a toluene solution of P3HT, followed by drying at 80° C. for 24 hours in a nitrogen environment.

(Formation of Drain Regions)

Prepared in a 300 ml beaker was a xylene solution of MEH-PPV (10 wt %), and 50 ml of an iodine solution was added thereinto, followed by ultrasonic stirring. It was followed by vacuum drying and brought into a film-like solid. This film-like solid was cut into lines having diameters of several mm, and the lines comprising the cut MEH-PPV were extruded by a melt extruder (manufactured by Imoto Machinery Co., Ltd.) into a fiber shape having a diameter of about 0.2 mm. There were prepared four fibers therefrom each having a length of about 10 cm.

The four fibers made of P3HT and each having the diameter of 0.2 mm were arranged on the linear body formed with the semiconductor layer. Ends of the fiber lines were fixed by an epoxy resin. This was followed by a heat treatment at 200° C. for 1 hour in a nitrogen environment, thereby welding the four drain regions to the insulating layer.

(Formation of Surface Protection Region)

The linear body formed with the drain regions was immersed into a dimethylformaldehyde solution of PMMA (polymethylmethacrylate) (5 wt %), followed by drying at 80° C. for 24 hours, thereby completing a linear device.

Measurement Test of Electric Characteristics

The fibers of the linear device fabricated in the production example were cut to have a length, i.e., a channel width W of 2 mm; gold lines were attached to the gate electrode, source regions, drain regions, and semiconductor region, respectively; and they were set in a darkroom to measure a drain current characteristic of the linear device by a semiconductor parameter measuring apparatus (4155 made by Agilent Technologies).

FIG. 5 is a graph of dependency of the measured drain currents on a drain voltage. The drain currents were measured by setting a gate voltage at 4V and 10V, respectively, while changing a drain voltage from −5V to 10V. The semiconductor region had the same electric potential as that of the source regions, and was connected to a ground potential. As a result, it was confirmed that higher gate voltages at a positive side increased a drain current so that the produced linear device was capable of functioning as an N-type MISFET.

### INDUSTRIAL APPLICABILITY

The MISFET has a structure for interposing a semiconductor region serving as a channel region between a source region(s) and a drain region(s) in a radial direction of a cross section of a device region, in a manner to determine a channel length by the film thickness of the semiconductor region. This enables downsizing, and improvement of reproducibility and uniformity, of the channel length.

Forming a hollow region at a center of the linear device enables a lightened weight of the linear body constituting the linear device. Alternatively, forming an electric conductor region enables a decreased electrode resistance or wiring resistance in the linear device. Alternatively, forming an insulating region facilitates electric separation of a plurality of linear devices formed in the linear body. Alternatively, forming a semiconductor region enables formation of a diode comprising a PN junction, for example, at the central part of the linear body. Forming a plurality of MISFETs in the longitudinal direction of a linear device facilitates formation of an integrated circuit comprising the linear device, thereby also effectively improving a degree of integration.

Forming the gate electrode, gate insulating region, source region(s), drain region(s), and/or semiconductor region from an organic semiconductor or electroconductive polymer, decreases a material cost and simplifies a production process, thereby effectively decreasing a production cost.

1. A linear device including a gate electrode, a gate insulating region, a source region, a drain region, and a semiconductor region, characterized in
that said semiconductor region is arranged between said source region comprising one or a plurality of source region(s) and said drain region comprising one or a plurality of drain region(s), in a radial direction within a cross section of a device region, so that a part of said gate insulating region is contacted with said semiconductor region.

2. The linear device of claim 1, wherein said gate electrode and said gate insulating region are arranged inside or outside said source region(s) and said drain region(s).

3. The linear device of claim 1, wherein said linear device comprises, at a center, one of: a hollow region; an electric conductor region; said gate electrode; said source region; said drain region; another insulating region different from said gate insulating region; and another semiconductor region different from said semiconductor region.

4. The linear device of claim 1, wherein said linear device comprises a plurality of device regions through separation regions therebetween, respectively, in a longitudinal direction of a linear body constituting said linear device.

5. The linear device of claim 1, wherein said gate electrode, gate insulating region, source region(s), drain region(s), and/or semiconductor region constituting said linear device are formed of an organic semiconductor or electroconductive polymer.

6. The linear device of claim 2, wherein said linear device comprises, at a center, one of: a hollow region; an electric conductor region; said gate electrode; said source region; said drain region; another insulating region different from said gate insulating region; and another semiconductor region different from said semiconductor region.

7. The linear device of claim 2, wherein said linear device comprises a plurality of device regions through separation regions therebetween, respectively, in a longitudinal direction of a linear body constituting said linear device.

8. The linear device of claim 3, wherein said linear device comprises a plurality of device regions through separation regions therebetween, respectively, in a longitudinal direction of a linear body constituting said linear device.

9. The linear device of claim 2, wherein said gate electrode, gate insulating region, source region(s), drain region(s), and/or semiconductor region constituting said linear device are formed of an organic semiconductor or electroconductive polymer.

10. The linear device of claim 3, wherein said gate electrode, gate insulating region, source region(s), drain region(s), and/or semiconductor region constituting said linear device are formed of an organic semiconductor or electroconductive polymer.

11. The linear device of claim 4, wherein said gate electrode, gate insulating region, source region(s), drain region(s), and/or semiconductor region constituting said linear device are formed of an organic semiconductor or electroconductive polymer.
